(19) United States
(12) Patent Application Publication
(10) Pub. No.: US 2026/0371667 A1
(43) Pub. Date: Nov. 19, 2026

(54) SEMICONDUCTOR DEVICE AND METHOD OF MANUFACTURING THE SAME

(71) Applicants: TAIWAN SEMICONDUCTOR MANUFACTURING COMPANY, LTD., Hsinchu (TW); TSMC NANJING COMPANY LIMITED, Nanjing (CN)

(72) Inventors: Huaixin XIAN, Nanjing City (CN); Zhang-Ying YAN, Nanjing City (CN); Qingchao MENG, Shanghai City (CN); Chia-Chun LIAO, Hsinchu City (TW); Chin-Hsien WANG, Hsinchu (TW)

(73) Assignees: TAIWAN SEMICONDUCTOR MANUFACTURING COMPANY, LTD., Hsinchu (TW); TSMC NANJING COMPANY LIMITED, Nanjing (CN)

(21) Appl. No.: 19/752,341

(22) Filed: Jul. 23, 2026

Related U.S. Application Data
(63) Continuation of application No. 18/630,807, filed on Apr. 9, 2024.

(30) Foreign Application Priority Data
Mar. 25, 2024 (CN) 202410346357.9

(51) Int. Cl. H10D 62/10; G05F 1/46; H10D 62/13; H10D 84/01; H10D 84/03; H10D 84/85; H10W 44/20

(52) U.S. Cl. CPC H10D 62/113; G05F 1/468; H10D 62/151; H10D 84/017; H10D 84/0172; H10D 84/038; H10D 84/85; H10W 44/20; H10W 44/248

(57) ABSTRACT

A semiconductor device includes a function circuit, an antenna circuit and a first isolation circuit. The function circuit is configured to receive a first reference voltage signal and a second reference voltage signal. The antenna circuit is configured to receive the first reference voltage signal to share charges with the function circuit. The first isolation circuit is disposed between the function circuit and the antenna circuit, and configured to receive the second reference voltage signal to isolate the function circuit and the antenna circuit from each other.

### CROSS - REFERENCE TO RELATED APPLICATION

This application is a continuation Application of U.S. Application serial number 18/630,807, filed Apr. 09, 2024, which claims priority benefit of China Application Serial Number 202410346357.9, filed Mar. 25, 2024, all of which are herein incorporated by reference in their entirety.

### BACKGROUND

A semiconductor device may include an antenna cell for protecting the semiconductor device from extra charges. However, when a voltage difference between the antenna cell and other parts of the semiconductor device is high, undesired leakage currents are induced between the antenna cell and the other parts of the semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a circuit diagram of a part of a semiconductor device, in accordance with some embodiments of the present disclosure.

FIG. 1B is a layout diagram of a part of a semiconductor device, in accordance with some embodiments of the present disclosure.

FIG. 2A is a circuit diagram of a part of a semiconductor device corresponding to the semiconductor device shown in FIG. 1A, in accordance with some embodiments of the present disclosure.

FIG. 2B is a layout diagram of a part of a semiconductor device corresponding to the semiconductor device shown in FIG. 1B, in accordance with some embodiments of the present disclosure.

FIG. 2C is a cross section diagram of a part of the semiconductor device shown in FIG. 2B, in accordance with some embodiments of the present disclosure.

FIG. 2D is a cross section diagram of a part of the semiconductor device shown in FIG. 2B, in accordance with some embodiments of the present disclosure.

FIG. 3A is a circuit diagram of a part of a semiconductor device corresponding to the semiconductor device shown in FIG. 1A, in accordance with some embodiments of the present disclosure.

FIG. 3B is a layout diagram of a part of a semiconductor device corresponding to the semiconductor device shown in FIG. 1B, in accordance with some embodiments of the present disclosure.

FIG. 3C is a schematic diagram corresponding to a side view of a part of the semiconductor device shown in FIG. 3B, in accordance with some embodiments of the present disclosure.

FIG. 3D is a schematic diagram corresponding to a side view of a part of the semiconductor device shown in FIG. 3B, in accordance with some embodiments of the present disclosure.

FIG. 3E is a schematic diagram corresponding to a side view of a part of the semiconductor device shown in FIG. 3B, in accordance with some embodiments of the present disclosure.

FIG. 3F is a schematic diagram corresponding to a side view of a part of the semiconductor device shown in FIG. 3B, in accordance with some embodiments of the present disclosure.

FIG. 4 is a flowchart diagram of a method of fabricating the semiconductor device shown in FIGS. 2B-2D or the semiconductor device as shown in FIGS. 3B-3F, in accordance with some embodiments of the present disclosure.

### DETAILED DESCRIPTION

The following disclosure provides many different embodiments, or examples, for implementing different features of the provided subject matter. Specific examples of components, materials, values, steps, arrangements or the like are described below to simplify the present disclosure. These are, of course, merely examples and are not intended to be limiting. Other components, materials, values, steps, arrangements or the like are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as "beneath," "below," "lower," "above," "upper" and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The terms applied throughout the following descriptions and claims generally have their ordinary meanings clearly established in the art or in the specific context where each term is used. Those of ordinary skill in the art will appreciate that a component or process may be referred to by different names. Numerous different embodiments detailed in this specification are illustrative only, and in no way limits the scope and spirit of the disclosure or of any exemplified term.

It is worth noting that the terms such as “first” and “second” used herein to describe various elements or processes aim to distinguish one element or process from another. However, the elements, processes and the sequences thereof should not be limited by these terms. For example, a first element could be termed as a second element, and a second element could be similarly termed as a first element without departing from the scope of the present disclosure.

In the following discussion and in the claims, the terms “comprising,” “including,” “containing,” “having,” “involving,” and the like are to be understood to be open-ended, that is, to be construed as including but not limited to. As used herein, instead of being mutually exclusive, the term "and/or" includes any of the associated listed items and all combinations of one or more of the associated listed items.

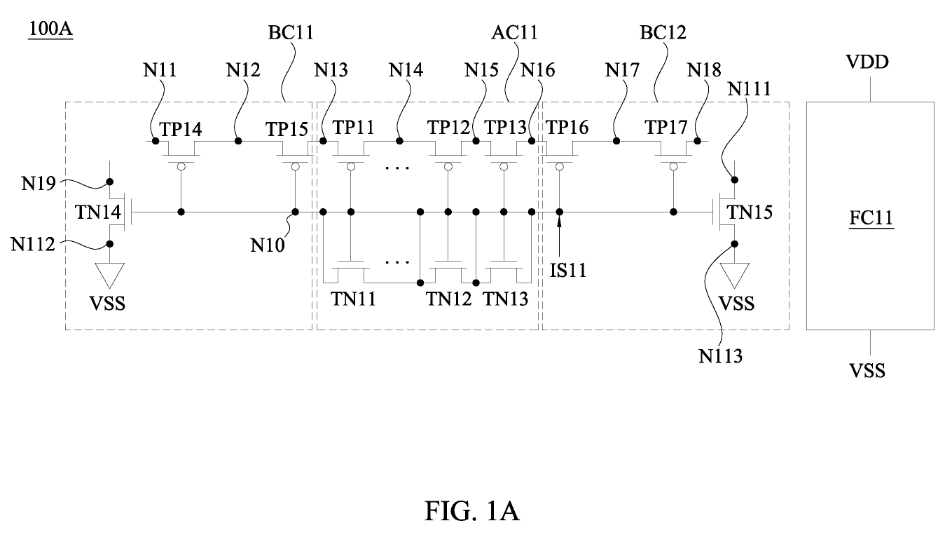

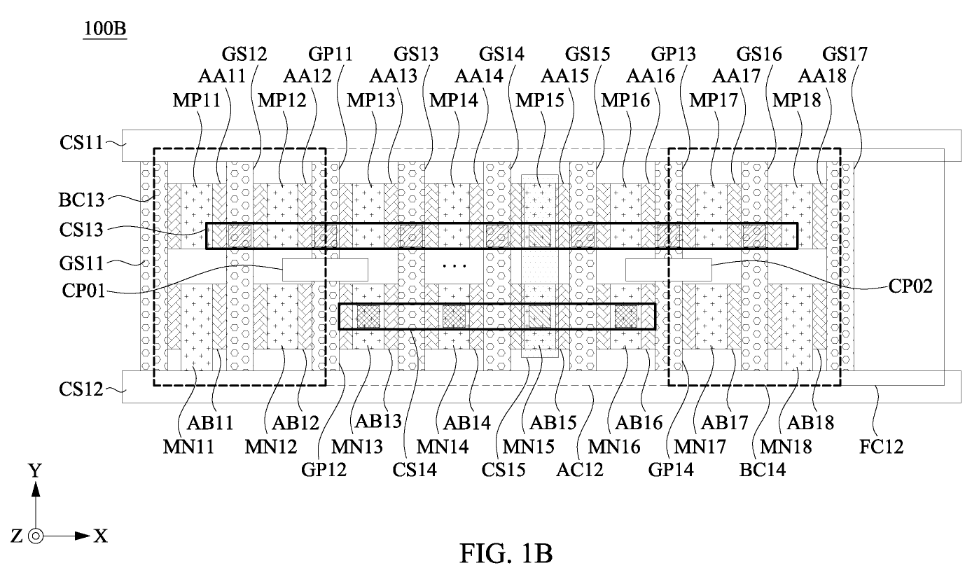

FIG. 1A is a circuit diagram of a part of a semiconductor device 100A, in accordance with some embodiments of the present disclosure. As illustratively shown in FIG. 1A, the semiconductor device 100A includes a function circuit FC11, an antenna circuit AC11 and isolation circuits BC11, BC12.

In some embodiments, the function circuit FC11 is configured to operate according to reference voltage signals VDD and VSS. In some embodiments, the function circuit FC11 is implemented by a standard cell, such as a logic cell including a logic circuit including AND, OR, NAND, MUX, Flip-flop, Latch, BUFF, inverter, or any other types of logic circuit. In some embodiments, a voltage level of the reference voltage signal VDD is higher than a voltage level of the reference voltage signal VSS. For example, the reference voltage signal VDD is implemented by a power signal, and the reference voltage signal VSS is implemented by a ground signal.

In some embodiments, the antenna circuit AC11 is configured to receive an input signal IS11 of the function circuit FC11 at a node N10, to share charges with the function circuit FC11. In some embodiments, the input signal IS11 is the reference voltage signal VDD. The isolation circuits BC11, BC12 are configured to isolate the antenna circuit AC11 from function circuits (such as the function circuit FC11) in the semiconductor device 100A, to reduce leakage currents between the antenna circuit AC11 and the function circuits.

As illustratively shown in FIG. 1A, the antenna circuit AC11 includes transistors TN11-TN13 and TP11-TP13. Each of control terminals of the transistors TN11-TN13 and TP11-TP13 is coupled to the node N10. A terminal of the transistor TP11 is coupled to a node N13, another terminal of the transistor TP11 is coupled to a node N14. A terminal of the transistor TP12 is coupled to the node N14, another terminal of the transistor TP12 is coupled to a node N15. A terminal of the transistor TP13 is coupled to the node N15, another terminal of the transistor TP13 is coupled to a node N16. Alternatively stated, the transistors TP11-TP13 are coupled in series between the nodes N13 and N16. In various embodiments, various numbers of transistors are coupled in series between the nodes N13 and N16, in which each of control terminals of the transistors is coupled to the node N10.

As illustratively shown in FIG. 1A, each of two terminals of the transistor TN11 is coupled to the node N10. Each of two terminals of the transistor TN12 is coupled to the node N10. Each of two terminals of the transistor TN13 is coupled to the node N10. In various embodiments, the antenna circuit AC11 includes various numbers of transistors coupled between the transistors TN11 and TN12 with two terminals being coupled to the node N10.

As illustratively shown in FIG. 1A, the isolation circuit BC11 includes transistors TN14, TP14 and TP15. Each of control terminals of the transistors TN14, TP14 and TP15 is coupled to the node N10. A terminal of the transistor TN14 is coupled to a node N19, another terminal of the transistor TN14 is configured to receive the reference voltage signal VSS at a node N112. A terminal of the transistor TP14 is coupled to a node N11, another terminal of the transistor TP14 is coupled to a node N12. A terminal of the transistor TP15 is coupled to the node N12, another terminal of the transistor TP15 is coupled to the node N13. In some embodiment, each of the nodes N11 and N19 is floated.

As illustratively shown in FIG. 1A, the isolation circuit BC12 includes transistors TN15, TP16 and TP17. Each of control terminals of the transistors TN15, TP16 and TP17 is coupled to the node N10. A terminal of the transistor TN15 is coupled to a node N111, another terminal of the transistor TN15 is configured to receive the reference voltage signal VSS at a node N113. A terminal of the transistor TP17 is coupled to a node N18, another terminal of the transistor TP17 is coupled to a node N17. A terminal of the transistor TP16 is coupled to the node N17, another terminal of the transistor TP16 is coupled to the node N16. In some embodiment, each of the nodes N111 and N18 is floated.

In some embodiments, the isolation circuits BC11 and BC12 are configured to operate as de-coupling capacitance circuits. The de-coupling capacitance circuits are configured as an essential component for stabilization of power supply voltages in standard cell circuits of integrated circuit operating in high speed. In some embodiments, the de-coupling capacitance circuits are inserted near function circuits (such as the function circuit FC11) of high transistoring activities so that their IR-drop can be suppressed.

In some embodiments, a conductive type of the transistors TP11-TP17 is different from a conductive type of the transistors TN11-TN15. For example, each of the transistors TP11-TP17 is implemented by P-type metal-oxide-semiconductor (PMOS) transistor, and each of the transistors TN11-TN15 is implemented by N-type metal-oxide-semiconductor (NMOS) transistor.

FIG. 1B is a layout diagram of a part of a semiconductor device 100B, in accordance with some embodiments of the present disclosure. As illustratively shown in FIG. 1B, the semiconductor device 100B includes a function circuit FC12, an antenna circuit AC12 and isolation circuits BC13, BC14. The isolation circuit BC13, the antenna circuit AC12, the isolation circuit BC14 and the function circuit FC12 are arranged in order along an X direction. Referring to FIGS. 1A and 1B and , the function circuit FC12, the antenna circuit AC12 and the isolation circuits BC13, BC14 are embodiments of the function circuit FC11, the antenna circuit AC11 and the isolation circuits BC11, BC12, respectively.

As illustratively shown in FIG. 1B, the semiconductor device 100B includes gate structures GS11-GS17, gate portions GP11-GP14, source/drain structures AA11-AA18, AB11-AB18 and conductive segments CS11-CS15, MP11-MP18, MN11-MN18, for forming the function circuit FC12, the antenna circuit AC12 and the isolation circuits BC13, BC14.

As illustratively shown in FIG. 1B, the conductive segments MP11-MP18, MN11-MN18 cross over and are coupled to the source/drain structures AA11-AA18, AB11-AB18, respectively. Alternatively stated, along a Z direction, the conductive segments MP11-MP18, MN11-MN18 are overlapped with the source/drain structures AA11-AA18, AB11-AB18, respectively.

Along the X direction, the gate structure GS11, the source/drain structure AA11, the gate structure GS12, the source/drain structure AA12, the gate portion GP11, the source/drain structure AA13, the gate structure GS13, the source/drain structure AA14, the gate structure GS14, the source/drain structure AA15, the gate structure GS15, the source/drain structure AA16, the gate portion GP13, the source/drain structure AA17, the gate structure GS16, the source/drain structure AA18, the gate structure GS17 are arranged in order.

Similarly, along the X direction, the gate structure GS11, the source/drain structure AB11, the gate structure GS12, the source/drain structure AB12, the gate portion GP12, the source/drain structure AB13, the gate structure GS13, the source/drain structure AB14, the gate structure GS14, the source/drain structure AB15, the gate structure GS15, the source/drain structure AB16, the gate portion GP14, the source/drain structure AB17, the gate structure GS16, the source/drain structure AB18, the gate structure GS17 are arranged in order.

In some embodiments, the gate portions GP11 and GPstructure AA13 are formed by cutting a gate structure extending along a Y direction with a separation spacer CP01. The gate portions GP13 and GP14 are formed by cutting another gate structure extending along the Y direction with a separation spacer CP02. Accordingly, along the Y direction, the gate portions GP11 and GP12 are aligned with and separated from each other, and the gate portions GP13 and GP14 are aligned with and separated from each other. In some embodiments, the X direction, the Y direction and the Z direction are perpendicular to each other.

In some embodiments, the separation spacer CP01 is arranged to isolate electronic signals transmitted through the gate portions GP11 and GP12. The separation spacer CP02 is arranged to isolate electronic signals transmitted through the gate portions GP13 and GP14. For illustration, the separation spacer CP01 is disposed between the gate portions GP11 and GP12 and the separation spacer CP02 is disposed between the gate portions GP13 and GP14. With the separation spacers CP01 and CP02, the electronic signal transmitted through the gate portion GP11 is isolated from the gate portion GP12 and the electronic signal transmitted through the gate portion GP13 is isolated from the gate portion GP14. In some embodiments, at least one of the separation spacers CP01 and CP02 is formed of a dielectric material. In some embodiments, the separation spacers CP01 and CP02 are poly cut layers, which are intermediate products during a semiconductor manufacturing procedure, and not existed in final products of the semiconductor circuit.

In some embodiments, each of the gate portions GP12 and GP14 is configured to operate as a dummy gate. Alternatively stated, each of the gate portions GP12 and GP14 does not operate as a control terminal of a transistor. In some embodiments, the dummy gate is a continuous polysilicon on oxide diffusion (OD) edge (CPODE) layout pattern.

As illustratively shown in FIG. 1B, each of the conductive segments CS11-CS14 extends along the X direction. The conductive segments CS12, CS14, CS13 and CS11 are separated from each other and arranged in order along the Y direction. Each of the conductive segments MN11 and MN18 extends along the Y direction to be coupled to the conductive segment CS12. In some embodiments, along the Y direction, a length of each of the conductive segments MN11 and MN18 is larger than a length of each of the conductive segments MN12-MN17.

As illustratively shown in FIG. 1B, the conductive segment CS13 crosses over the gate structures GS12-GS16, the conductive segments MP12-MP17, the gate portions GP11, GP13 and the source/drain structures AA12-AA17. The conductive segment CS13 is coupled to the gate structures GS12-GS16 and the gate portions GP11, GP13 through corresponding vias. Each of the vias coupled to the conductive segment CS13 is interposed between corresponding two of the source/drain structures AA11-AA18 along the X direction.

As illustratively shown in FIG. 1B, the conductive segment CS14 crosses over the gate structures GS13-GS15, the conductive segments MN13-MN16 and the source/drain structures AB13-AB16. The conductive segment CS14 is coupled to the source/drain structures AB13-AB16 through corresponding vias. The conductive segment CS15 crosses over the conductive segments CS13 and CS14, and is coupled to the conductive segments CS13 and CS14 through corresponding vias.

In some embodiments, a conductive type of the source/drain structures AB11-AB18 is different from a conductive type of the source/drain structures AA11-AA18. For example, the source/drain structures AB11-AB18 are implemented by N-type oxide diffusion (OD) material, and the source/drain structures AA11-AA18 are implemented by P-type OD material. In some embodiments, the gate structures GS11-GS17 and the gate portions GP11-GP14 are implemented by poly-silicon. In some embodiments, the conductive segments CS11-CS14 are disposed in a metal-zero (M0) layer, and the conductive segment CS15 is disposed in a metal-one (M1) layer above the M0 layer.

Referring to FIGS. 1A and 1B , in some embodiments, the transistor TN14 is implemented by the gate structure GS12 and the source/drain structures AB11, AB12. The transistor TP14 is implemented by the gate structure GS12 and the source/drain structures AA11, AA12. The transistor TP15 is implemented by the gate portion GP11 and the source/drain structures AA13, AA12.

In some embodiments, the transistor TN11 is implemented by the gate structure GS13 and the source/drain structures AB13, AB14. The transistor TP11 is implemented by the gate structure GS13 and the source/drain structures AA13, AA14. The transistor TN12 is implemented by the gate structure GS14 and the source/drain structures AB14, AB15. The transistor TP12 is implemented by the gate structure GS14 and the source/drain structures AA14, AA15. The transistor TN13 is implemented by the gate structure GS15 and the source/drain structures AB15, AB16. The transistor TP13 is implemented by the gate structure GS15 and the source/drain structures AA15, AA16.

In some embodiments, the transistor TN15 is implemented by the gate structure GS16 and the source/drain structures AB17, AB18. The transistor TP17 is implemented by the gate structure GS16 and the source/drain structures AA17, AA18. The transistor TP16 is implemented by the gate portion GP13 and the source/drain structures AA17, AA16.

In some embodiments, the conductive segment CS11 is configured to transmit the reference voltage signal VDD, and the conductive segment CS12 is configured to transmit the reference voltage signal VSS through the conductive segments MN11 and MN18 to the source/drain structures AB11 and AB18. In some embodiments, the conductive segment CS15 is configured to transmit the reference voltage signal VDD from higher metal layers through the conductive segments CS13 and CS14 to the gate structures GS12-GS16, the gate portions GP11, GP13 and the source/drain structures AB13-AB16. In some embodiments, the function circuit is configured to receive the reference voltage signal VDD from the conductive segment CS11, and is configured to receive the reference voltage signal VSS from the conductive segment CS12.

Referring to FIGS. 1A and 1B , the nodes N11-N113 correspond to the conductive segments MP11-MP18, MN11, CS15, MN17, MN12 and MN18, respectively. The conductive segments MN13-MN16, the gate structures GS12-GS16 and the gate portions GP11, GP13 are coupled to the node N10, to share charges of the reference voltage signal VDD. Each of the nodes N19 and N111 is floated and has a logic potential of the reference voltage signal VSS. Accordingly, the function circuit FC12 is protected from the charges corresponding to the reference voltage signal VDD. Accordingly, the function circuits (such as the function circuit FC12) are isolated from the antenna circuit AC12 by the isolation circuits BC13 and BC14.

In some approaches, a filler is inserted between an antenna circuit and a function circuit, to reduce leakage currents between the antenna circuit and the function circuit. However, additional areas are required for forming the filler.

Compared to the above approaches, in some embodiments of the present disclosure, the isolation circuit BC14 is configured to share charges by the gate structure GS16, and is also configured to isolate the antenna circuit AC12 and the function circuit FC12, to reduce leakage currents between the antenna circuit AC12 and the function circuit FC12. Accordingly, no additional areas are required for isolating the antenna circuit AC12 and the function circuit FC12.

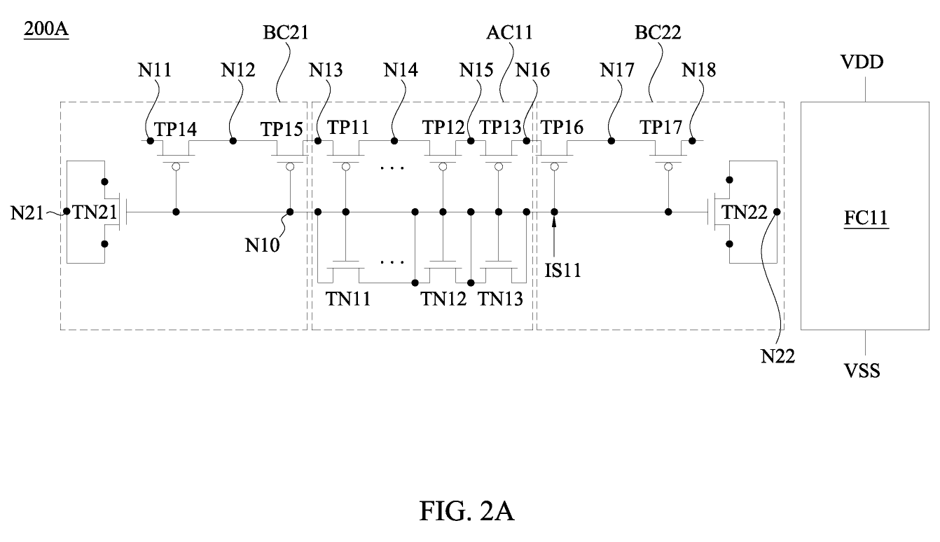

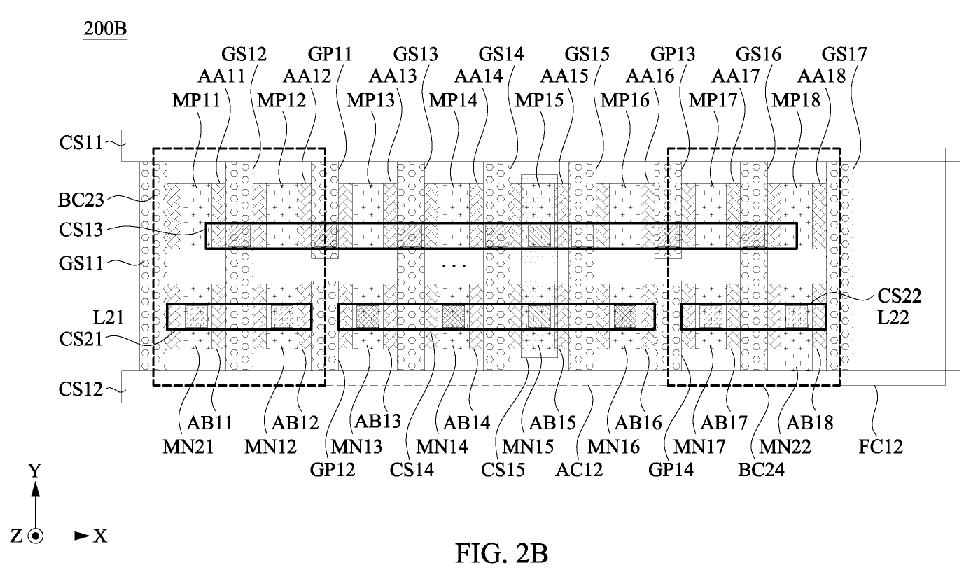

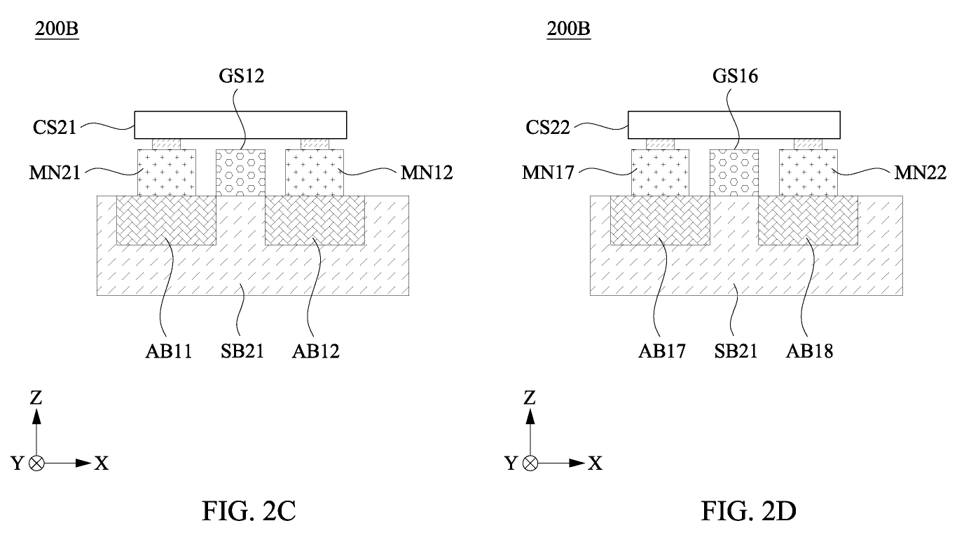

FIG. 2A is a circuit diagram of a part of a semiconductor device 200A corresponding to the semiconductor device 100A shown in FIG. 1A, in accordance with some embodiments of the present disclosure. Referring to FIGS. 2A and 1A , the semiconductor device 200A is an alternative embodiment of the semiconductor device 100A. FIG. 2A follows a similar labeling convention to that of FIG. 1A. For brevity, the discussion will focus more on differences between FIGS. 2A and 1A than on similarities.

Comparing with the semiconductor device 100A, the semiconductor device 200A includes isolation circuits BC21 and BC22 instead of the isolation circuits BC11 and BC12. Comparing with the isolation circuit BC11, the isolation circuit BC21 includes a transistor TN21 instead of the transistor TN14. Comparing with the isolation circuit BC12, the isolation circuit BC22 includes a transistor TN22 instead of the transistor TN15.

As illustratively shown in FIG. 2A, a control terminal of the transistor TN21 is coupled to the node N10, and two terminals of the transistor TN21 are coupled to each other at a node N21. A control terminal of the transistor TN22 is coupled to the node N10, and two terminals of the transistor TN22 are coupled to each other at a node N22. In some embodiment, each of the nodes N21 and N22 is floated.

FIG. 2B is a layout diagram of a part of a semiconductor device 200B corresponding to the semiconductor device 100B shown in FIG. 1B, in accordance with some embodiments of the present disclosure. Referring to FIGS. 2B and 1B , the semiconductor device 200B is an alternative embodiment of the semiconductor device 100B. FIG. 2B follows a similar labeling convention to that of FIG. 1B. For brevity, the discussion will focus more on differences between FIGS. 2B and 1B , than on similarities.

Comparing with the semiconductor device 100B, the semiconductor device 200B includes isolation circuits BC23 and BC24 instead of the isolation circuits BC13 and BC14. Referring to FIGS. 2A and 2B , the isolation circuits BC23 and BC24 are embodiments of the isolation circuits BC21 and BC22, respectively.

Furthermore, comparing with the semiconductor device 100B, the semiconductor device 200B includes conductive segments MN21 and MN22 instead of the conductive segments MN11 and MN18. The conductive segments MN21 and MN22 are configured to be formed as part of the isolation circuits BC23 and BC24, respectively.

As illustratively shown in FIG. 2B, the conductive segments MN21 and MN22 cross over and are coupled to the source/drain structures AB11 and AB18, respectively. Along the X direction, the conductive segment MN21 is disposed between the gate structures GS11 and GS12, and the conductive segment MN22 is disposed between the gate structures GS16 and GS17. Along the Y direction, a length of the conductive segment MN21 is same as the length of each of the conductive segments MN12-MN17.

Referring to FIGS. 2B and 18 , comparing with the semiconductor device 100B, the semiconductor device 200B further includes conductive segments CS21 and CS22. Each of the conductive segments CS21 and CS22 extends along the X direction. The conductive segment CS21 crosses over the conductive segments MN21, MN12 and the gate structure GS12, and is coupled to the conductive segments MN21 and MN12 through corresponding vias. The conductive segment CS22 crosses over the conductive segments MN22, MN17 and the gate structure GS16, and is coupled to the conductive segments MN22 and MN17 through corresponding vias.

Referring to FIGS. 2B and 2A , in some embodiments, the transistor TN21 is implemented by the gate structure GS12 and the source/drain structures AB11, AB12. The transistor TN22 is implemented by the gate structure GS16 and the source/drain structures AB17, AB18. The nodes N21 and N22 correspond to the conductive segments CS21 and CS22, respectively.

In some embodiments, the isolation circuits BC23 and BC24 isolate the function circuits (such as the function circuit FC12) of the semiconductor device 200B from the antenna circuit AC11. Accordingly, leakage currents between the antenna circuit AC11 and the function circuits are reduced.

FIG. 2C is a cross section diagram of a part of the semiconductor device 200B shown in FIG. 2B, in accordance with some embodiments of the present disclosure. Referring to FIGS. 2B and 2C , the cross section diagram shown in FIG. 2C corresponds to a line L21 shown in FIG. 2B.

As illustratively shown in FIG. 2C, the semiconductor device 200B further includes a substrate SB21. In some embodiments, the substrate SB21 is implemented by P-type material. Each of the source/drain structures AB11 and AB12 is embedded in the substrate SB21. The conductive segments MN21 and MN12 contact with the source/drain structures AB11 and AB12, respectively. The conductive segment CS21 is coupled to the conductive segments MN21 and MN12 through corresponding vias, and is separated from the gate structure GS12 along the Z direction.

FIG. 2D is a cross section diagram of a part of the semiconductor device 200B shown in FIG. 2B, in accordance with some embodiments of the present disclosure. Referring to FIGS. 2B and 2D , the cross section diagram shown in FIG. 2D corresponds to a line L22 shown in FIG. 2B.

As illustratively shown in FIG. 2D, each of the source/drain structures AB17 and AB18 is embedded in the substrate SB21. The conductive segments MN22 and MN17 contact with the source/drain structures AB18 and AB17, respectively. The conductive segment CS22 is coupled to the conductive segments MN21 and MN12 through corresponding vias, and is separated from the gate structure GS16 along the Z direction.

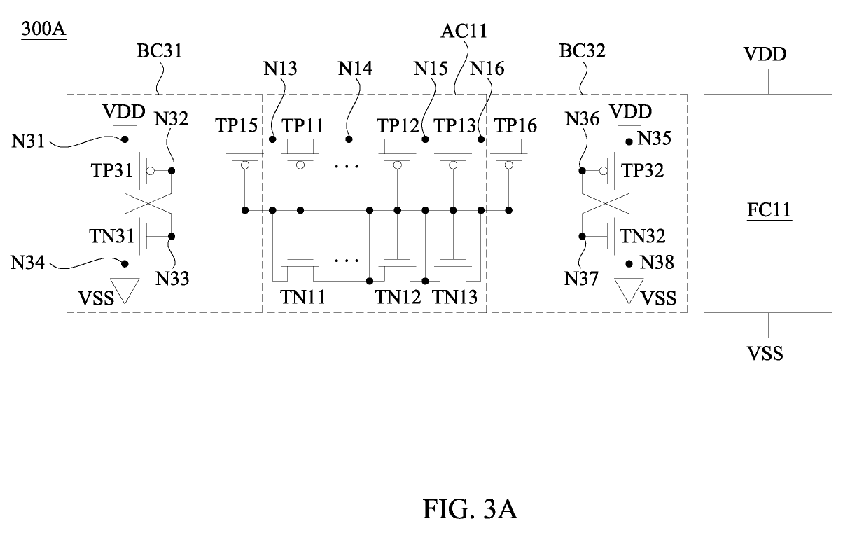

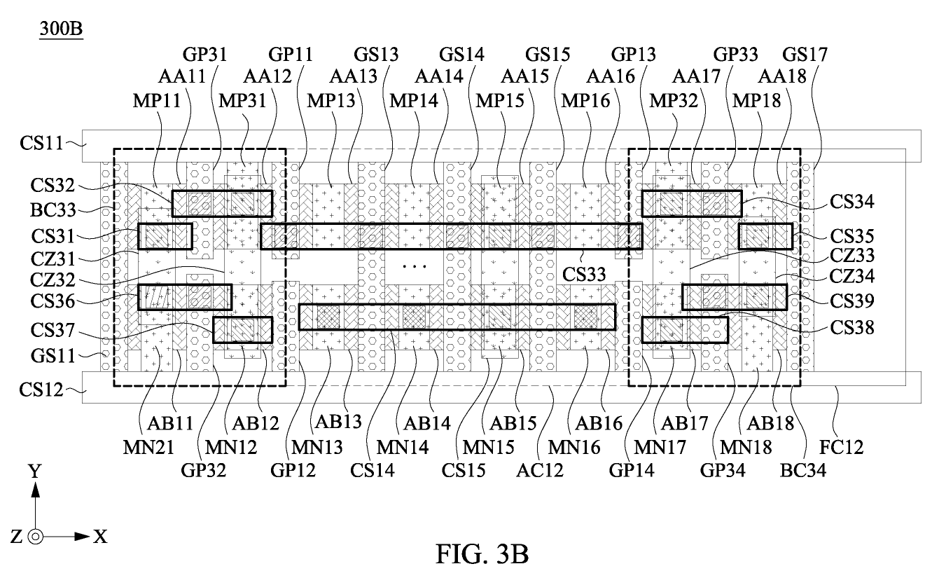

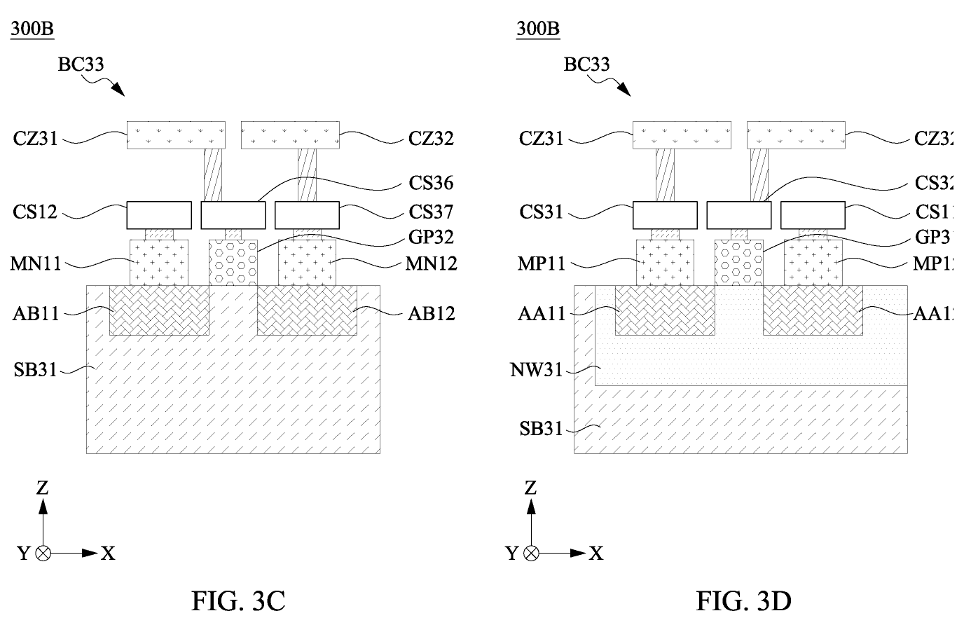

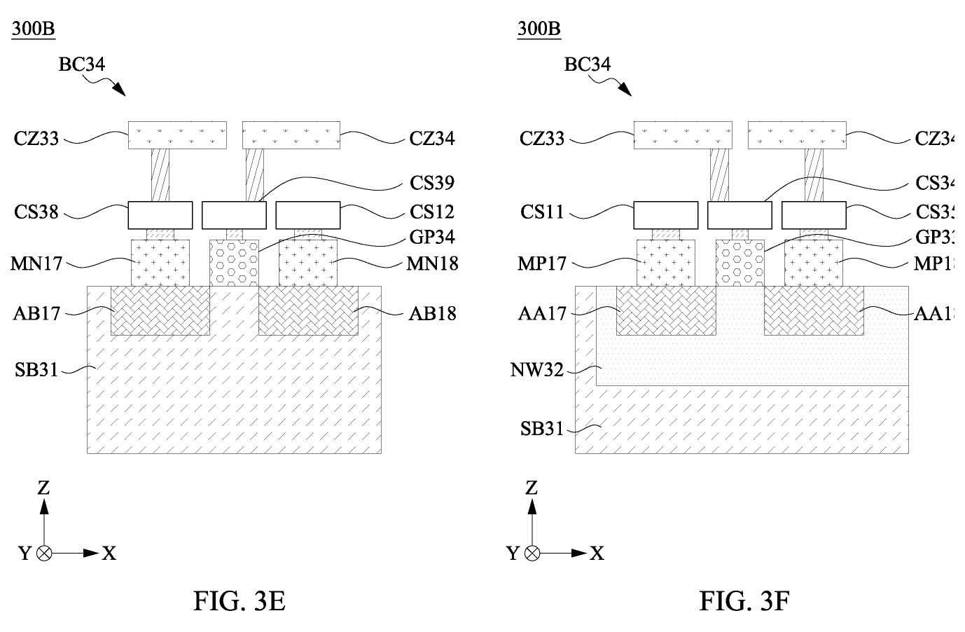

FIG. 3A is a circuit diagram of a part of a semiconductor device 300A corresponding to the semiconductor device 100A shown in FIG. 1A, in accordance with some embodiments of the present disclosure. Referring to FIGS. 3A and 1A , the semiconductor device 300A is an alternative embodiment of the semiconductor device 100A. FIG. 3A follows a similar labeling convention to that of FIG. 1A. For brevity, the discussion will focus more on differences between FIGS. 3A and 1A, and than on similarities.

Comparing with the semiconductor device 100A, the semiconductor device 300A includes isolation circuits BC31 and BC32 instead of the isolation circuits BC11 and BC12. Comparing with the isolation circuit BC11, the isolation circuit BC31 includes transistors TN31 and TP31 instead of the transistors TN14 and TP14. Comparing with the isolation circuit BC12, the isolation circuit BC32 includes transistors TN32 and TP32 instead of the transistors TN15 and TP17. Furthermore, the transistors TP15 and TP16 are coupled to nodes N31 and N35, respectively, instead of being coupled to the transistors TP14 and TP17.

As illustratively shown in FIG. 3A, a control terminal of the transistor TN31 is coupled to a node N33, a terminal of the transistor TN31 is coupled to a node N32, and another terminal of the transistor TN31 is configured to receive the reference voltage signal VSS at a node N34. A control terminal of the transistor TP31 is coupled to the node N32, a terminal of the transistor TP31 is coupled to the node N33, and another terminal of the transistor TP31 is configured to receive the reference voltage signal VDD at the node N31. A control terminal of the transistor TN32 is coupled to a node N37, a terminal of the transistor TN32 is coupled to a node N36, and another terminal of the transistor TN32 is configured to receive the reference voltage signal VSS at a node N38. A control terminal of the transistor TP32 is coupled to the node N36, a terminal of the transistor TP32 is coupled to the node N37, and another terminal of the transistor TP32 is configured to receive the reference voltage signal VDD at the node N35.

During operations, each of the transistors TN31, TN32, TP31 and TP23 is turned on. Each of the nodes N32 and N36 has the voltage level of the reference voltage signal VSS. Each of the nodes N33 and N37 has the voltage level of the reference voltage signal VDD. Accordingly, the antenna circuit AC11 is isolated from function circuits (such as the function circuit FC11) in the semiconductor device 300A by the isolation circuits BC31 and BC32.

FIG. 3B is a layout diagram of a part of a semiconductor device 300B corresponding to the semiconductor device 100B shown in FIG. 1B, in accordance with some embodiments of the present disclosure. Referring to FIGS. 3B and 1B , the semiconductor device 300B is an alternative embodiment of the semiconductor device 100B. FIG. 3B follows a similar labeling convention to that of FIG. 1B. For brevity, the discussion will focus more on differences between FIGS. 2B and 1B , than on similarities.

Comparing with the semiconductor device 100B, the semiconductor device 300B includes isolation circuits BC33 and BC34 instead of the isolation circuits BC13 and BC14. Referring to FIGS. 3A and 3B , the isolation circuits BC33 and BC34 are embodiments of the isolation circuits BC31 and BC32, respectively.

Furthermore, comparing with the semiconductor device 100B, the semiconductor device 300B includes conductive segments MP31, MP32, CS31-CS39, CZ31-CZ34 and gate portions GP31-GP34 instead of the conductive segments MP12, MP17, CS13 and the gate structures GS12, GS16.

As illustratively shown in FIG. 3B, the conductive segments MP31 and MP32 cross over and are coupled to the source/drain structures AA12 and AA17, respectively. Each of the conductive segments MP31 and MP32 is coupled to the conductive segment CS11 and has a length longer than the length of each of the conductive segments MP11-MP18 along the Y direction.

As illustratively shown in FIG. 3B, along the X direction, the gate portion GP31 is disposed between the source/drain structures AA11 and AA12, the gate portion GP32 is disposed between the source/drain structures AB11 and AB12, the gate portion GP33 is disposed between the source/drain structures AA17 and AA18, and the gate portion GP34 is disposed between the source/drain structures AB17 and AB18.

As illustratively shown in FIG. 3B, the conductive segment CS31 crosses over the conductive segment MP11. The conductive segment CS32 crosses over the gate portion GP31 and the conductive segment MP31. The conductive segment CS33 crosses over the gate portions GP11, GP13 and the gate structures GS13-GS15. The conductive segment CS34 crosses over the gate portion GP33 and the conductive segment MP32. The conductive segment CS35 crosses over the conductive segment MP18.

In some embodiments, the conductive segment CS31 is coupled to the conductive segment MP11 through a corresponding via. The conductive segment CS32 is coupled to the gate portion GP31 through a corresponding via, and is separated from the conductive segment MP31 along the Z direction. The conductive segment CS33 is coupled to the gate portions GP11, GP13 and the gate structures GS13-GS15 through corresponding vias. Each of the vias coupled to the conductive segment CS33 is interposed between corresponding two of the source/drain structures AA12-AA17 along the X direction.

In some embodiments, the conductive segment CS34 is coupled to the gate portion GP33 through a corresponding via, and is separated from the conductive segment MP32 along the Z direction. The conductive segment CS35 is coupled to the conductive segment MP18 through a corresponding via.

As illustratively shown in FIG. 3B, the conductive segment CS36 crosses over the gate portion GP32 and the conductive segment MN11. The conductive segment CS37 crosses over the conductive segment MN12. The conductive segment CS38 crosses over the conductive segment MN17. The conductive segment CS39 crosses over the gate portion GP34 and the conductive segment MN18.

In some embodiments, the conductive segment CS37 is coupled to the conductive segment MN12 through a corresponding via. The conductive segment CS36 is coupled to the gate portion GP32 through a corresponding via, and is separated from the conductive segment MN11 along the Z direction. The conductive segment CS39 is coupled to the gate portion GP34 through a corresponding via, and is separated from the conductive segment MN18 along the Z direction. The conductive segment CS38 is coupled to the conductive segment MN17 through a corresponding via.

In some embodiments, the gate portions GP31 and GP32 are formed by cutting a gate structure extending along a Y direction, and the gate portions GP33 and GP34 are formed by cutting another gate structure extending along the Y direction. Accordingly, along the Y direction, the gate portions GP31 and GP32 are aligned with and separated from each other, and the gate portions GP33 and GP34 are aligned with and separated from each other.

As illustratively shown in FIG. 3B, the conductive segment CZ31 crosses over and is coupled to each of the conductive segments CS31 and CS36. The conductive segment CZ32 crosses over and is coupled to each of the conductive segments CS32 and CS37. The conductive segment CZ33 crosses over and is coupled to each of the conductive segments CS34 and CS38. The conductive segment CZ34 crosses over and is coupled to each of the conductive segments CS35 and CS39. In some embodiments, the conductive segments CS31-CS39 are disposed in the M0 layer, and the conductive segments CZ31-CZ34 are disposed in the M1 layer.

Referring to FIGS. 3B and 3A , in some embodiments, the transistor TN31 is implemented by the gate portion GP32 and the source/drain structures AB11, AB12. The transistor TP31 is implemented by the gate portion GP31 and the source/drain structures AA11, AA12. The transistor TN32 is implemented by the gate portion GP34 and the source/drain structures AB17, AB18. The transistor TP32 is implemented by the gate portion GP33 and the source/drain structures AA17, AA18. The nodes N31-N38 correspond to the conductive segments MP31, CZ32, CZ31, MN11, MP32, CZ33, CZ34 and MN18, respectively.

In some embodiments, the isolation circuits BC33 and BC34 isolate the function circuits (such as the function circuit FC12) of the semiconductor device 300B from the antenna circuit AC11. Accordingly, leakage currents between the antenna circuit AC11 and the function circuits are reduced.

FIG. 3C is a schematic diagram corresponding to a side view of a part of the semiconductor device 300B shown in FIG. 3B, in accordance with some embodiments of the present disclosure. Referring to FIGS. 3B and 3C , the schematic diagram shown in FIG. 3C corresponds to the isolation circuit BC33 shown in FIG. 3B.

As illustratively shown in FIG. 3C, the semiconductor device 300B further includes a substrate SB31. In some embodiments, the substrate SB31 is implemented by P-type material. Each of the source/drain structures AB11 and AB12 is embedded in the substrate SB31. The conductive segments MN11 and MN12 contact with the source/drain structures AB11 and AB12, respectively.

As illustratively shown in FIG. 3C, the conductive segment CS12 is coupled to the conductive segments MN11 through a corresponding via, and is separated from the conductive segment CZ31 along the Z direction. The conductive segment CS36 is coupled to the gate portion GP32 and the conductive segment CZ31 through corresponding vias. The conductive segment CS37 is coupled to the conductive segments CZ32 and MN12 through corresponding vias.

FIG. 3D is a schematic diagram corresponding to a side view of a part of the semiconductor device 300B shown in FIG. 3B, in accordance with some embodiments of the present disclosure. Referring to FIGS. 3B and 3D , the schematic diagram shown in FIG. 3D corresponds to the isolation circuit BC33 shown in FIG. 3B.

As illustratively shown in FIG. 3D, the semiconductor device 300B further includes a well NW31. In some embodiments, the well NW31 is implemented by N-type material. Each of the source/drain structures AA11 and AA12 is embedded in the well NW31. The conductive segments MP11 and MP31 contact with the source/drain structures AA11 and AA12, respectively.

As illustratively shown in FIG. 3D, the conductive segment CS11 is coupled to the conductive segments MP31 through a corresponding via, and is separated from the conductive segment CZ32 along the Z direction. The conductive segment CS32 is coupled to the gate portion GP31 and the conductive segment CZ32 through corresponding vias. The conductive segment CS31 is coupled to the conductive segments CZ31 and MP11 through corresponding vias.

FIG. 3E is a schematic diagram corresponding to a side view of a part of the semiconductor device 300B shown in FIG. 3B, in accordance with some embodiments of the present disclosure. Referring to FIGS. 3B and 3E , the schematic diagram shown in FIG. 3E corresponds to the isolation circuit BC34 shown in FIG. 3B.

As illustratively shown in FIG. 3E, each of the source/drain structures AB17 and AB18 is embedded in the substrate SB31. The conductive segments MN17 and MN18 contact with the source/drain structures AB17 and AB18, respectively.

As illustratively shown in FIG. 3E, the conductive segment CS12 is coupled to the conductive segments MN18 through a corresponding via, and is separated from the conductive segment CZ34 along the Z direction. The conductive segment CS39 is coupled to the gate portion GP34 and the conductive segment CZ34 through corresponding vias. The conductive segment CS38 is coupled to the conductive segments CZ33 and MN17 through corresponding vias.

FIG. 3F is a schematic diagram corresponding to a side view of a part of the semiconductor device 300B shown in FIG. 3B, in accordance with some embodiments of the present disclosure. Referring to FIGS. 3B and 3F , the schematic diagram shown in FIG. 3F corresponds to the isolation circuit BC34 shown in FIG. 3B.

As illustratively shown in FIG. 3F, the semiconductor device 300B further includes a well NW32. In some embodiments, the well NW32 is implemented by N-type material. Each of the source/drain structures AA17 and AA18 is embedded in the well NW32. The conductive segments MP17 and MP38 contact with the source/drain structures AA17 and AA18, respectively.

As illustratively shown in FIG. 3F, the conductive segment CS11 is coupled to the conductive segments MP37 through a corresponding via, and is separated from the conductive segment CZ33 along the Z direction. The conductive segment CS34 is coupled to the gate portion GP33 and the conductive segment CZ33 through corresponding vias. The conductive segment CS35 is coupled to the conductive segments CZ34 and MP18 through corresponding vias.

In some embodiments, at least one of the semiconductor devices 100A, 100B, 200A, 200B, 300A and 300B is formed by a semiconductor manufacturing system. The semiconductor manufacturing system is configured to receive information associated with at least one of the semiconductor devices 100A, 100B, 200A, 200B, 300A and 300B. In some embodiments, The semiconductor manufacturing system includes fabrication tools to manufacture an integrated circuit using a set of masks manufactured based on one or more layout designs of at least one of the semiconductor devices 100A, 100B, 200A, 200B, 300A and 300B.

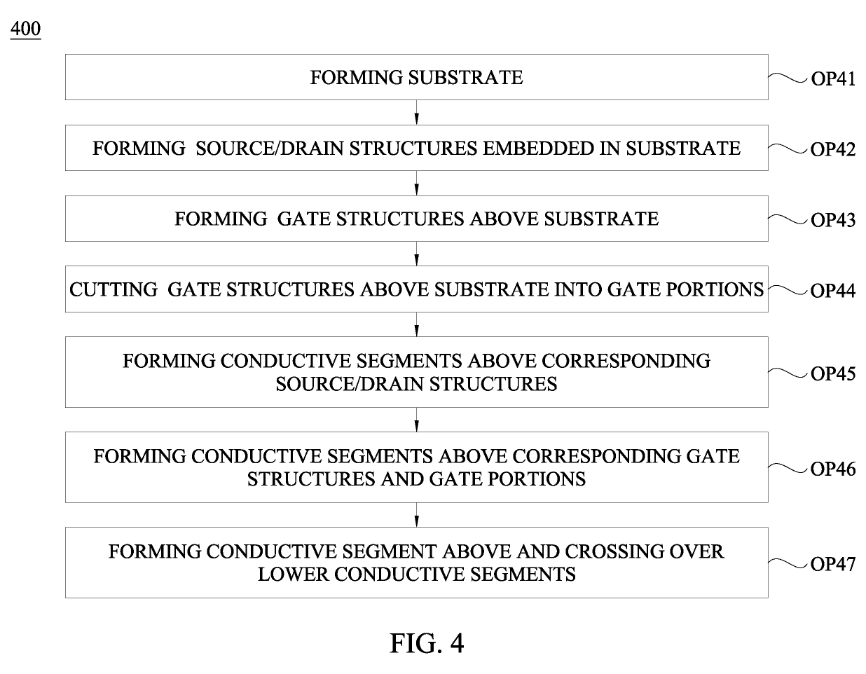

FIG. 4 is a flowchart diagram of a method 400 of fabricating the semiconductor device 200B shown in FIGS. 2B-2D or the semiconductor device 300B as shown in FIGS. 3B-3F, in accordance with some embodiments of the present disclosure. As illustratively shown in FIG. 4, the method 400 includes operations OP41-OP47. In some embodiments, the operations OP41-OP47 are performed in order.

At the operation OP41, the substrate SB21 is formed.

At the operation OP42, the source/drain structures AA11-AA18 and AB11-AB18 are formed to be embedded in the substrate SB21.

At the operation OP43, the gate structures GS11-GS17 and the gate structures corresponding to the gate portions GP11-GP14 are formed above the substrate SB21.

At the operation OP44, the gate structures corresponding to the gate portions GP11-GP14 are cut into the gate portions GP11-GP14.

At the operation OP45, the conductive segments MP11-MP17, MN12-MN17, MN21 and MN22 are formed above the corresponding source/drain structures AA11-AA18 and AB11-AB18.

At the operation OP46, the conductive segments CS11-CS14 and CS21-CS22 are formed above the corresponding gate structures GS11-GS17, the corresponding gate portions GP11-GP14 and the corresponding conductive segments MP11-MP17, MN12-MN17, MN21, MN22.

At the operation OP47, the conductive segment CS15 is formed above the conductive segments CS11-CS14 and CS21-CS22, and is crosses over the conductive segments CS13 and CS14.

Also disclosed is a semiconductor device. The semiconductor device includes a function circuit, an antenna circuit and a first isolation circuit. The function circuit is configured to receive a first reference voltage signal and a second reference voltage signal. The antenna circuit is configured to receive the first reference voltage signal to share charges with the function circuit. The first isolation circuit is disposed between the function circuit and the antenna circuit, and configured to receive the second reference voltage signal to isolate the function circuit and the antenna circuit from each other.

Also disclosed is a semiconductor device. The semiconductor device includes a first gate structure, a first gate portion, a second gate portion and a first source/drain structure. The first gate structure and a second gate structure are configured to receive a first reference voltage signal. The first gate portion is disposed between the first gate structure and the second gate structure along a first direction and configured to receive the first reference voltage signal. The second gate portion is separated from the first gate portion. The first source/drain structure and a second source/drain structure are coupled together and configured to receive the first reference voltage signal. The first source/drain structure, the second gate structure, the second source/drain structure and the first gate structure are arranged in order along the first direction.

Also disclosed is a method. The method includes: forming a first source/drain structure, a second source/drain structure, and a third source/drain structure that are arranged in order along a first direction; forming a first gate portion between the first source/drain structure and the second source/drain structure; forming a first gate structure between the first source/drain structure and the second source/drain structure; cutting the first gate structure into a first gate portion and a second gate portion wherein the second gate portion is aligned with and separated from the first gate portion along a second direction different from the first direction; and forming a first conductive segment extending along the first direction. The first source/drain structure is coupled to the second gate portion, the third source/drain structure is coupled to the first conductive segment, and the second source/drain structure and the third source/drain structure are configured to be two terminals of a first transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first gate structure corresponding to a first transistor, and configured to receive a first reference voltage signal;
a first source/drain structure and a second source/drain structure corresponding to two terminals of the first transistor;
a first conductive segment configured to transmit a second reference voltage signal different from the first reference voltage signal;
a second conductive segment configured to couple the first conductive segment to the first source/drain structure; and
a third conductive segment coupled to the second source/drain structure and isolated from the first conductive segment.

2. The semiconductor device of claim 1, wherein each of the first source/drain structure and the second conductive segment is separated from the first conductive segment along a direction, and
the second conductive segment is longer than the third conductive segment along the direction.

3. The semiconductor device of claim 1, further comprising:
a third source/drain structure corresponding to a second transistor; and
a fourth conductive segment crossing over the third source/drain structure and coupled to the first gate structure,
wherein the first gate structure further corresponds to the second transistor.

4. The semiconductor device of claim 3, wherein a conductive type of the first transistor is different from a conductive type of the second transistor.

5. The semiconductor device of claim 3, further comprising:
a first gate portion correspond to a third transistor, and coupled to the fourth conductive segment,
wherein the third source/drain structure further corresponds to the third transistor.

6. The semiconductor device of claim 5, further comprising:
a second gate portion adjacent to the second source/drain structure, and configured to operate as a dummy gate,
wherein the first gate portion and the second gate portion are cut from one gate structure.

7. The semiconductor device of claim 6, further comprising:
a fourth source/drain structure adjacent to the second gate portion; and
a fifth conductive segment crossing over and coupled to the fourth source/drain structure, and configured to receive the first reference voltage signal.

8. The semiconductor device of claim 3, further comprising:
a second gate structure corresponding to a third transistor, and coupled to the fourth conductive segment;
a fourth source/drain structure and a fifth source/drain structure corresponding to two terminals of the third transistor;
a fifth conductive segment configured to couple the first conductive segment to the fourth source/drain structure; and
a sixth conductive segment coupled to the fifth source/drain structure and isolated from the first conductive segment.

9. The semiconductor device of claim 8, wherein each of the fourth source/drain structure and the fifth conductive segment is separated from the first conductive segment along a direction, and
the fifth conductive segment is longer than the sixth conductive segment along the direction.

10. A semiconductor device, comprising:
a first gate structure corresponding to a first transistor;
a first source/drain structure and a second source/drain structure corresponding to two terminals of the first transistor; and
a first conductive segment crossing over each of the first source/drain structure and the second source/drain structure, and configured to couple the first source/drain structure and the second source/drain structure to each other.

11. The semiconductor device of claim 10, wherein the first conductive segment crosses over and is isolated from the first gate structure.

12. The semiconductor device of claim 10, further comprising:
a first gate portion;
a third source/drain structure disposed between the first gate portion and the first gate structure; and
a second conductive segment crossing over the third source/drain structure, and coupled to each of the first gate portion and the first gate structure.

13. The semiconductor device of claim 12, further comprising:
a second gate structure corresponding to a second transistor, and coupled to the second conductive segment;
a fourth source/drain structure and a fifth source/drain structure corresponding to two terminals of the second transistor; and
a third conductive segment crossing over each of the fourth source/drain structure and the fifth source/drain structure, and configured to couple the fourth source/drain structure and the fifth source/drain structure to each other.

14. The semiconductor device of claim 12, further comprising:
a second gate portion adjacent to the first source/drain structure, and configured to operate as a dummy gate,
wherein the first gate portion and the second gate portion are cut from one gate structure.

15. The semiconductor device of claim 14, further comprising:
a fourth source/drain structure adjacent to the second gate portion; and
a third conductive segment crossing over and coupled to the fourth source/drain structure,
wherein the second gate portion is interposed between the third conductive segment and the first conductive segment is a layout view.

16. A method, comprising:
forming a first source/drain structure and a second source/drain structure that are arranged in order along a first direction;
forming a first gate structure between the first source/drain structure and the second source/drain structure;
cutting the first gate structure into a first gate portion and a second gate portion, wherein the second gate portion is aligned with and separated from the first gate portion along a second direction different from the first direction;
forming a first conductive segment and a second conductive segment above the first source/drain structure and the second source/drain structure, respectively; and
forming a third conductive segment separated from each of the first source/drain structure and the second source/drain structure along the second direction,
wherein the first conductive segment is isolated from the third conductive segment, and the second conductive segment is coupled to the third conductive segment.

17. The method of claim 16, further comprising:
forming a third source/drain structure and a fourth source/drain structure that are arranged in order along the first direction, wherein the first gate portion is disposed between the third source/drain structure and the fourth source/drain structure;
forming a fourth conductive segment and a fifth conductive segment above the third source/drain structure and the fourth source/drain structure, respectively; and
forming a sixth conductive segment separated from each of the third source/drain structure and the fourth source/drain structure along the second direction,
wherein the fifth conductive segment is isolated from the sixth conductive segment, and the fourth conductive segment is coupled to the sixth conductive segment.

18. The method of claim 17, wherein each of the first source/drain structure and the second source/drain structure has a first conductive type, and
each of the third source/drain structure and the fourth source/drain structure has a second conductive type different from the first conductive type.

19. The method of claim 17, further comprising:
forming a seventh conductive segment crossing over and coupled to the second gate portion; and
forming an eighth conductive segment coupled to each of the seventh conductive segment and the fourth source/drain structure.

20. The method of claim 17, further comprising:
forming a seventh conductive segment crossing over and coupled to the first gate portion; and
forming an eighth conductive segment coupled to each of the seventh conductive segment and the first source/drain structure.
